(19) United States
(12) Patent Application Publication
(10) Pub. No.: US 2007/0272950 A1
(43) Pub. Date: Nov. 29, 2007

(54) SEMICONDUCTOR MEMORY DEVICES AND METHODS OF FABRICATING THE SAME

(75) Inventors: Rak-Hwan KIM, Gyeonggi-do (KR); Kyung-Chang RYOO, Gyeonggi-do (KR); In-Sun PARK, Seoul (KR); Yoon-Jong SONG, Seoul (KR); Hyeon-Deok LEE, Seoul (KR); Hyun-Seok LIM, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/753,291

(22) Filed: May 24, 2007

(30) Foreign Application Priority Data
May 24, 2006 (KR) 10-2006-46662

(51) Int. Cl. H01L 27/10

(52) U.S. Cl. 257/211

(57) ABSTRACT

A method of fabricating a semiconductor memory device includes forming a first insulating layer and a sacrificial layer on a substrate. The first insulating layer and the sacrificial layer have an opening therein. A first conductive layer is formed in the opening and on the sacrificial layer. A second insulating layer is formed on the first conductive layer. The second insulating layer, the first conductive layer and the sacrificial layer are then planarized until the first insulating layer is exposed, thereby forming a first conductive pattern and a second insulating layer pattern in the opening. A phase change material layer is formed on the first conductive pattern, the first insulating layer and the second insulating layer pattern. A second conductive pattern is formed on the phase change material layer. A semiconductor memory device and a data processing system adopting the semiconductor memory device are also provided.

### CROSS-REFERENCE TO RELATED APPLICATION

This application claims the benefit of Korean Patent Application No. 10-2006-46662, filed May 24, 2006, the disclosure of which is incorporated herein by reference in its entirety.

### BACKGROUND

1. Field of Invention

Embodiments of the present invention relate generally to semiconductor memory devices and, more particularly, to phase change memory devices and methods of fabricating the same.

2. Description of the Related Art

Phase change material may have at least two different states, for example, a crystalline state, an amorphous state and at least one mixed state therebetween. Thus, the phase change material may be employed in a semiconductor memory device such as a phase change memory device. Amorphous phase change material exhibits a first resistivity, and crystalline phase change material exhibits a second resistivity which is lower than the first resistivity. Further, phase change material having the mixed state exhibits a third resistivity between the first and second resistivities. Crystalline phase change material may be converted into the amorphous phase change material or vice versa. Hence, the phase change material may act as a programmable resistor. The crystalline structure of phase change material may be changed according to heat applied thereto. The heat may be generated by applying an electrical signal such as a current to the phase change material through electrodes. The resistivity of the phase changeable material is corresponds to a contact area between the phase change material and the electrode. As the contact area decreases, the current for heating the change material to change its state also decreases. Accordingly, it is desirable to reduce the contact area between the electrode and the phase change material.

### SUMMARY

Embodiments disclosed herein are generally directed to semiconductor memory devices and methods of fabricating the same.

One embodiment exemplarily described herein can generally be characterized as a method of forming a semiconductor memory device that includes forming a first insulating layer pattern and a sacrificial layer on a substrate. The sacrificial layer may have an etch selectivity with respect to the first insulating layer pattern. An opening may be defined within the first insulating layer pattern and the sacrificial layer. A preliminary first conductive pattern may be formed on a sidewall of the opening. A preliminary second insulating layer pattern may be formed on the preliminary first conductive pattern within the opening. At least a portion of at least one of the preliminary first conductive pattern and the preliminary second insulating layer pattern may be over the first insulating layer pattern. The sacrificial layer and portions of the preliminary first conductive pattern and the preliminary second insulating layer pattern over the first insulating layer pattern may be removed to form a first conductor and a second insulating layer. A phase change material layer may be formed on the first conductor, the first insulating layer pattern and the second insulating layer pattern. A second conductor may be formed on the phase change material layer.

Another embodiment exemplarily described herein can generally be characterized as a method of forming a semiconductor memory device that includes forming a first insulating layer pattern and a sacrificial layer on a substrate. The sacrificial layer may have an etch selectivity with respect to the first insulating layer pattern. An opening may be defined within the first insulating layer pattern and the sacrificial layer. A preliminary first conductive pattern may be formed on a sidewall and a bottom surface of the opening. A preliminary second insulating layer pattern may be formed on the preliminary first conductive pattern to substantially fill the opening. At least a portion of at least one of the preliminary first conductive pattern and the preliminary second insulating layer pattern may be over the first insulating layer pattern. The sacrificial layer and portions of the preliminary first conductive pattern and the preliminary second insulating layer pattern over the first insulating layer pattern may be removed to form a first conductor and a second insulating layer pattern. A phase change material layer may be formed on the first conductor, the first insulating layer pattern and the second insulating layer pattern. A second conductor may be formed on the phase change material layer.

Still another embodiment exemplarily described herein can generally be characterized as a semiconductor memory cell including a first insulating layer pattern on a substrate. The first insulating layer pattern has an opening defined therein. At least a sidewall of the opening is covered with a first conductor. A second insulating layer pattern is within the opening. A phase change material layer is disposed on the first insulating layer pattern, the first conductor and the second insulating layer pattern. A second conductor is provided on the phase change material layer. Each of the first insulating layer and the second insulating layer pattern may comprise a material such as silicon nitride, silicon oxynitride or a combination thereof.

Yet another embodiment exemplarily described herein can generally be characterized as a phase change memory cell including a first insulating layer pattern on a substrate. The first insulating layer pattern has an opening defined therein. A second insulating layer pattern is within the opening. A first conductor is between at least a portion of a sidewall of the opening and the second insulating layer pattern. A protection spacer is on at least one sidewall of the first conductor adjoining the top surface of the first conductor. A phase change material layer is disposed on the first conductor, the protection spacer and at least one of the first insulating layer pattern and the second insulating layer pattern. A second conductor is provided on the phase change material layer.

A further embodiment exemplarily described herein can generally be characterized as a data processing system that includes a processor and a memory device in communication with the processor. The memory device may include at least one phase change memory device having a plurality of phase change memory cells. Each of the phase change memory cells may include a first insulating layer pattern on a substrate. The first insulating layer pattern has an opening defined therein. At least a sidewall of the opening is covered with a first conductor. A second insulating layer pattern is within the opening. A phase change material layer is disposed on the first insulating layer pattern, the first conductor and the second insulating layer pattern. A second conductor is provided on the phase change material layer. Each of the first insulating layer and the second insulating layer pattern may comprise a material such as silicon nitride, silicon oxynitride or a combination thereof.

### BRIEF DESCRIPTION OF THE DRAWINGS

FIG. 1 is a schematic sectional view illustrating a phase change memory cell according to one embodiment;

FIG. 2 is a schematic plan view illustrating a phase change memory cell according to some embodiments;

FIG. 3 is a schematic sectional view illustrating a phase change memory cell according to another embodiment;

FIG. 4 is a schematic sectional view illustrating a phase change memory cell according to still another embodiment;

FIGS. 5 to 12 are cross sectional views illustrating a method of fabricating a phase change memory cell according to one embodiment;

FIG. 13 is a schematic sectional view illustrating a phase change memory cell according to yet another embodiment;

FIG. 14 is a schematic sectional view illustrating a phase change memory cell according to yet still another embodiment;

FIG. 15 is a schematic sectional view illustrating a phase change memory cell according to a further embodiment;

FIG. 16 is a schematic sectional view illustrating a phase change memory cell according to a still further embodiment;

FIGS. 17 to 20 are cross sectional views illustrating a method of fabricating a phase change memory cell according to another embodiment;

FIGS. 21 and 22 are cross sectional views illustrating a method of fabricating a phase change memory cell according to still another embodiment; and

FIG. 23 is a block diagram illustrating a data processing system adopting a phase change memory device.

### DETAILED DESCRIPTION

Exemplary embodiments disclosed herein will now be described more fully hereinafter with reference to the accompanying drawings. These embodiments may, however, be realized in different forms and should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout the specification.

It will be understood that when a material layer such as a conductive layer, a semiconductor layer or an insulating layer is referred to as being “on” or extending “onto” another element, it can be directly on or extend directly onto the other element or intervening elements may also be present. Further, it will be understood that, although the terms first, second, third, etc. may be used herein to describe various material layers or process steps, these material layers or process steps should not be limited by these terms. These terms are only used to distinguish one material layer (or process step) from another. As used herein, the term “and/or” includes any and all combinations of one or more of the associated listed items.

In the specification, “a substrate” may comprise an arbitrary semiconductor based structure having a silicon surface. The semiconductor based structure may comprise a silicon substrate, a silicon-on-insulator (SOI) substrate, a doped or undoped silicon layer, a silicon epitaxial layer supported by a semiconductor structure, or another semiconductor structure. The semiconductor structure may comprise a silicon-germanium (SiGe) layer, a germanium layer or a gallium arsenide (GaAs) layer. Further, the “substrate” may be a substrate on which an insulation layer and/or a conductive layer are formed.

According to some embodiments, a method of a phase change memory device may comprise removing a portion of a conductive layer or an insulating layer using an appropriate etchant such as a wet etchant or an etching gas after formation of the conductive layer or the insulating layer on a substrate having another conductive layer and/or another insulating layer. Methods of fabricating a phase change memory device according to some embodiments may comprise selectively etching a certain conductive layer or a certain insulating layer while another conductive layer or another insulating layer adjacent to the certain conductive layer or the certain insulating layer is substantially not etched.

Generally, embodiments disclosed herein are related to phase change memory devices and methods of fabricating the same. In particular, some embodiments are directed to phase change memory devices having a small contact area between a phase change material layer and an electrode and fabrication methods thereof. According to some embodiments, the contact area between the phase change material layer and the electrode may exhibit a closed loop configuration such as a circular ring, an oval-shaped ring or a polygonal shape. For instance, the electrode may have a closed loop configuration when viewed from a top plan view and the entire top surface of the electrode may be in contact with the phase change material layer.

The closed loop configuration may exhibit a curved shape such as a circular ring or an oval ring, or a polygonal shape such as a tetragonal ring. In the embodiments exemplarily described below, it is assumed that the electrode has a circular ring shape.

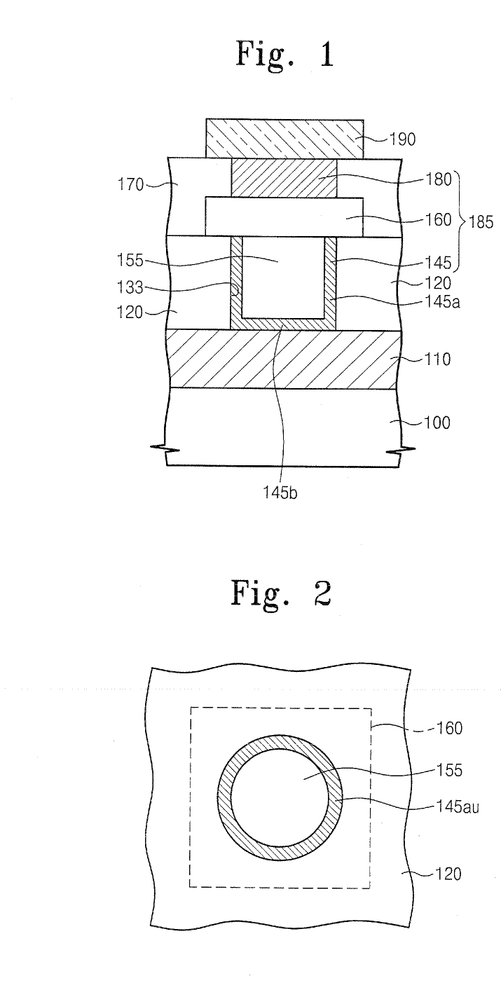

FIG. 1 is a cross sectional view illustrating a phase change memory cell according to one embodiment.

Referring to FIG. 1, the phase change memory cell 185 may be disposed on a substrate 100. The phase change memory cell 185 comprises a first conductor (i.e., a first conductive pattern) 145, a second conductor (i.e., a second conductive pattern) 180 and a phase change material layer 160 interposed therebetween. The first conductor 145 may act as a bottom electrode of the phase change memory cell 185 and may be electrically connected to a first interconnection 110 formed on the substrate 100. The second conductor 180 may act as a top electrode of the phase change memory cell 185 and may be electrically connected to a second interconnection 190.

A first insulating layer pattern 120 may be disposed between the first interconnection 110 and the phase change material layer 160 and the first conductor 145 may be located in an opening 133 that penetrates the first insulating layer pattern 120. For example, the first conductor 145 may be disposed on a bottom surface and on a sidewall of the opening 133. Accordingly, the first conductor 145 may comprise a vertical portion 145a covering the sidewall of the opening 133 and a horizontal portion 145b covering the bottom surface of the opening 133. A region surrounded by the first conductor 145 may be substantially filled with a second insulating layer pattern 155. As a result, an outer sidewall of the first conductor 145 (i.e., an outer sidewall of the vertical portion 145a) may be in contact with the first insulating layer pattern 120, and an inner wall of the first conductor 145 (i.e., an inner sidewall of the vertical portion 145a and a top surface of the horizontal portion 145b) may be in contact with the second insulating layer pattern 155. Further, a top surface of the first conductor 145 (i.e., a top surface of the vertical portion 145a) may contact the phase change material layer 160, and a bottom surface of the horizontal portion 145b may contact the first interconnection 110.

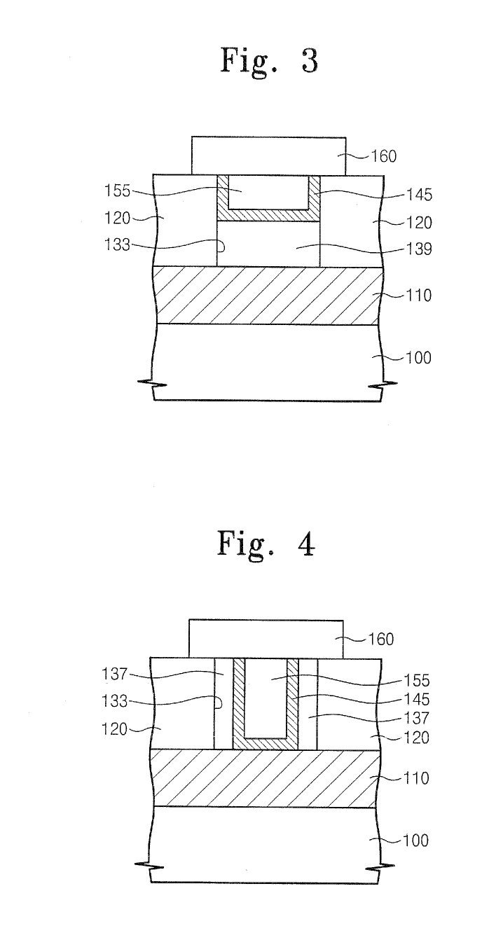

The phase change material layer 160 may be in contact with top surfaces of the first conductor 145, the first insulating layer pattern 120 and the second insulating layer pattern 155. A geometrical shape of the top surface 145au of the first conductor 145 may exhibit a closed loop configuration such as a circular ring as shown in a top plan view of FIG. 2. Thus, according to an embodiment, a contact area between the first conductor 145 and the phase change material layer 160 may be minimized.

The phase change material layer 160 may comprise any material that can be convertible between at least two states by an electrical signal (e.g., a current pulse signal) applied to the phase change material layer 160 through the conductors 145 and 180. For example, the phase change material layer 160 may be a chalcogenide compound layer. The chalcogenide compound layer may comprise Ge—Sb—Te, As—Sb—Te, As—Ge—Sb—Te, Sn—Sb—Te, In—Sn—Sb—Te, Ag—In—Sb—Te, Group 5A element-Sb—Te, Group 6A element-Sb—Te, group 5A element-Sb—Se, Group 6A element-Sb—Se, Ge—Sb—Te—Si, As—Sb—Te—Si, As—Ge—Sb—Te—Si, Sn—Sb—Te—Si, In—Sn—Sb—Te—Si, Ag—In—Sb—Te—Si, Group 5A element-Sb—Te—Si, Group 6A element-Sb—Te—Si, Group 5A element-Sb—Se—Si, Group 6A element-Sb—Se—Si, or the like or combinations thereof.

In some embodiments, adjacent layers of phase change material may be isolated from each other. In other embodiments, adjacent layers of phase change material may be contact each other.

The first conductor 145 may, for example, comprise a conductive material containing nitrogen, a conductive material containing carbon, titanium, tungsten, molybdenum, tantalum, titanium silicide, tantalum silicide or the like, or combinations thereof. The conductive material containing nitrogen may, for example, comprise titanium nitride (TiN), tantalum nitride (TaN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAIN), tantalum silicon nitride (TaSiN), tantalum aluminum nitride (TaAlN) layer, titanium oxynitride (TiON) layer, titanium aluminum oxynitride (TiAlON), tungsten oxynitride (WON), tantalum oxynitride (TaON) or the like, or combinations thereof. The conductive material containing carbon may comprise, for example, graphite.

The second conductor 180 may, for example, comprise aluminum, tungsten silicide, copper, titanium tungsten, tantalum, molybdenum, tungsten, an alloy of aluminum and copper, an alloy of aluminum, copper and silicon or the like, or combinations thereof.

The first interconnection 110 may, for example, comprise aluminum, tungsten silicide, copper, titanium tungsten, tantalum, molybdenum, tungsten, an alloy of aluminum and copper, an alloy of aluminum, copper and silicon or the like, or combinations thereof. The second interconnection 190 may, for example, comprise aluminum, an alloy of aluminum and copper, an alloy of aluminum, copper and silicon, tungsten silicide, copper, titanium tungsten, tantalum, molybdenum, tungsten or the like, or combinations thereof.

The second interconnection 190 may act as a data line such as bit line capable of transmitting logic information stored in the phase change material layer 160 to a sense amplifier (not shown) or vice versa, and the first interconnection 110 may act as a selection line such as a word line capable of selecting the phase change material layer 160.

The first insulating layer pattern 120 may, for example, comprise silicon oxide, silicon oxynitride or the like, or combinations thereof. The second insulating layer pattern 155 may, for example, comprise silicon oxide, silicon oxynitride or the like, or combinations thereof. In an embodiment, the first insulating layer pattern 120 may be the same material layer as the second insulating layer pattern 155. For example, the first and second insulating layers 120 and 155 may comprise silicon nitride or silicon oxynitride. In the event that each of the first and second insulating layers 120 and 155 comprise a multi-layered insulating structure, a top-most layer of the first insulating layer pattern 120 may be the same material layer as that of the second insulating layer pattern 155. That is, the first insulating layer pattern 120 contacting the phase change material layer 160 may be the same material as the second insulating layer pattern 155 contacting the phase change material layer 160.

The phase change material layer 160 may be in direct contact with the top surface 145au of the first conductor 145 and may not be in contact with the inner and outer sidewalls of the first conductor 145, in order to minimize the contact area between the phase change material layer 160 and the first conductor 145. For example, the outer sidewall of the first conductor 145 may be completely covered with the first insulating layer pattern 120, and the inner wall of the first conductor 145 may be completely covered with the second insulating layer pattern 155. In this case, the top surface of the first insulating layer pattern 120 may have the substantially same level as that of the second insulating layer pattern 155, as shown in FIG. 1.

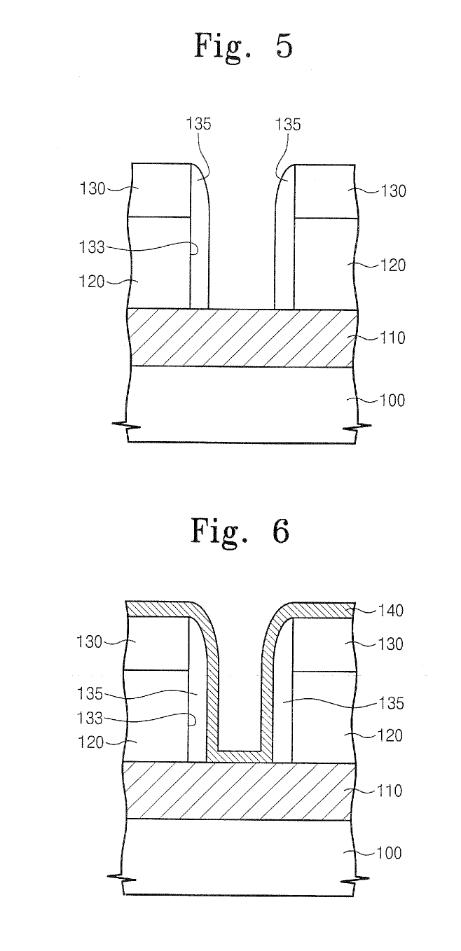

In other embodiments, a third conductor 139 having a low resistivity may be provided between the first conductor 145 and the first interconnection 110, as shown in FIG. 3. The third conductor 139 may improve a contact resistance characteristic between the first conductor 145 and the first interconnection 110.

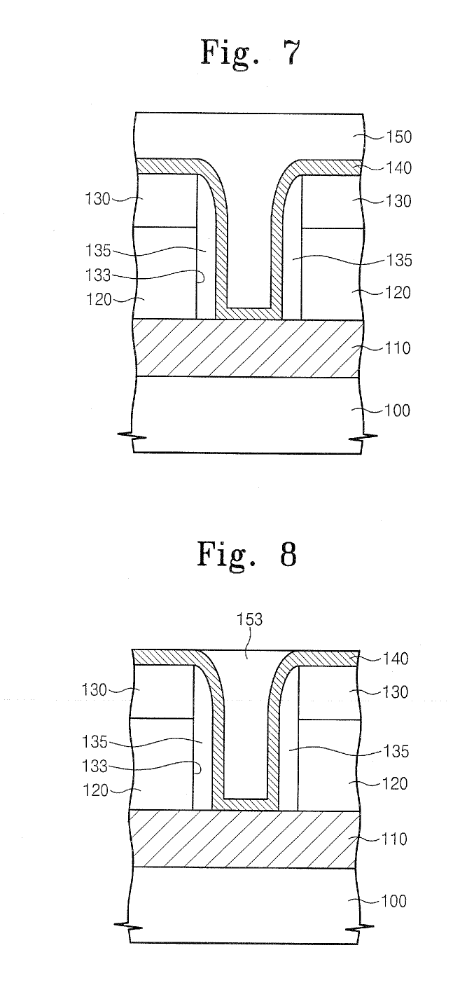

In further embodiments, an insulating spacer 137 may be disposed between the first conductor 145 and the first insulating layer pattern 120, as shown in FIG. 4. The insulating spacer 137 include silicon nitride, or silicon oxynitride, or the like, or combinations thereof. The contact area between the first conductor 145 and the phase change material layer 160 may be significantly reduced because of the presence of the insulating spacer 137, as compared to the embodiments shown in FIGS. 1 and 3.

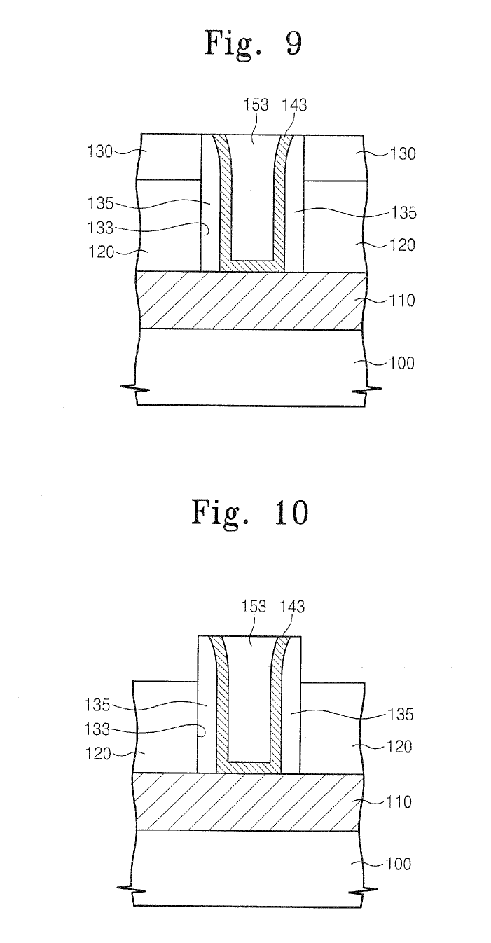

Exemplary methods of fabricating a phase change memory cell according to the embodiments of the invention will now be described with reference to FIGS. 5 to 12.

Referring to FIG. 5, a first interconnection 110 is formed on a substrate 100. The first interconnection 110 may, for example, comprise aluminum, tungsten silicide, copper, titanium tungsten, tantalum, molybdenum, tungsten, an alloy of aluminum and copper, an alloy layer of aluminum, copper and silicon, or the like or combinations thereof. A first insulating layer pattern 120 is formed on the substrate 100 and the first interconnection 110. The first insulating layer pattern 120 may, for example, comprise silicon oxide, silicon oxynitride, or the like or combinations thereof. A sacrificial layer 130 is formed on the first insulating layer pattern 120. The sacrificial layer 130 may be formed of a material layer having an etching selectivity with respect to the first insulating layer pattern 120. For example, the sacrificial layer 130 may comprise silicon oxide, silicon, aluminum oxide, titanium oxide, or the like or combinations thereof. The sacrificial layer 130 and the first insulating layer pattern 120 are patterned to form an opening 133 that exposes the first interconnection 110.

An insulating spacer 135 may be formed on a sidewall of the opening 133. The insulating spacer 135 may be formed of a material layer having an etching selectivity with respect to the sacrificial layer 130. For example, the insulating spacer 135 may be formed by depositing a material layer such as silicon oxide or silicon oxynitride on the substrate having the opening 133 and etching back the material layer. In some embodiments, a process for forming the spacer 135 may be omitted.

Referring to FIG. 6, a first conductive layer 140 is formed on the substrate having the insulating spacer 135. The first conductive layer 140 may, for example, comprise titanium, tungsten, molybdenum, tantalum, titanium silicide, tantalum silicide, a conductive material containing nitrogen, a conductive material containing carbon, or the like or combinations thereof. The conductive material containing nitrogen may, for example, comprise titanium nitride (TiN), tantalum nitride (TaN), molybdenum nitride (MoN), niobium nitride (NbN), titanium silicon nitride (TiSiN), titanium aluminum nitride (TiAlN), titanium boron nitride (TiBN), zirconium silicon nitride (ZrSiN), tungsten silicon nitride (WSiN), tungsten boron nitride (WBN), zirconium aluminum nitride (ZrAlN), molybdenum silicon nitride (MoSiN), molybdenum aluminum nitride (MoAlN), tantalum silicon nitride (TaSiN), tantalum aluminum nitride (TaAlN), titanium oxynitride (TiON), titanium aluminum oxynitride (TiAlON), tungsten oxynitride (WON), tantalum oxynitride (TaON), or the like or combinations thereof. The conductive material containing carbon may, for example, comprise graphite.

In the event that the first conductive layer 140 comprises titanium nitride (TiN), the first conductive layer 140 may be formed using a chemical vapor deposition (CVD) technique that employs a tetra chloride titanium (TiCl₄) gas as a source gas or a metal organic chemical vapor deposition (MOCVD) technique that employs tetrakis di-methyl amino titanium (Ti(N(CH₃)₂)₄; TDMAT) as metal organic precursor.

Referring to FIG. 7, a second insulating layer 150 is formed on the first conductive layer 140. The second insulating layer 150 may be formed to substantially fill the opening 133 surrounded by the first conductive layer 140. The second insulating layer 150 may be formed of a material layer having an etching selectivity with respect to the sacrificial layer 130. For example, the second insulating layer 150 may be formed of a material such as silicon oxide, silicon nitride layer, or the like or combinations thereof. Further, the second insulating layer 150 may be formed of the same material as the first insulating layer pattern 120.

Referring to FIG. 8, the second insulating layer 150 may be planarized to expose a top surface of the first conductive layer 140 on the sacrificial layer 130. As a result, a preliminary second insulating layer pattern 153 is formed in the opening 133 and is laterally surrounded by the first conductive layer 140. The planarization of the second insulating layer 150 may be achieved by an etch-back process, a chemical mechanical polishing (CMP) process, or the like or combinations thereof. The etch-back process may be performed using a dry etching technique and/or a wet etching technique.

Referring to FIG. 9, portions of the first conductive layer 140 outside the opening 133 are removed to expose an upper portion (e.g., the top surface) of the sacrificial layer 130. As a result, a preliminary first conductor (i.e., a preliminary first conductive pattern) 143 may be formed in the opening 133 and is laterally surrounded by the insulating spacer 135. The portions of the first conductive layer 140 outside the opening 133 may be selectively removed using a first planarization process such as an etch-back process, a CMP process, or the like or combinations thereof. The sacrificial layer 130 and the preliminary second insulating layer pattern 153 may act as planarization stop layers during the first planarization process.

Referring to FIG. 10, the sacrificial layer 130 may be selectively removed. As a result, the insulating spacer 135, the preliminary second insulating layer pattern 153 and the preliminary first conductive pattern 143 protrude above the first insulating layer pattern 120. The sacrificial layer 130 may be removed using a dry etching technique and/or a wet etching technique.

Referring to FIG. 11, the protruding portions of the spacer 135, the preliminary first conductive pattern 143 and the preliminary second insulating layer pattern 153 may be removed to form a planarized spacer 137, a first conductive pattern 145 and the second insulating layer pattern 155, the top surfaces of which are substantially coplanar with the top surface of the first insulating layer pattern 120. The protruding portions of the spacer 135, the preliminary first conductive pattern 143 and the preliminary second insulating layer pattern 153 may be removed using a second planarization process such as an etch-back process, a CMP process, or the like or combinations thereof. In this case, the first insulating layer pattern 120 may act as a planarization stop layer. For example, if the first insulating layer pattern 120, the second insulating layer 150 and the insulating spacer 135 are formed of the same material layer, the top surfaces of the planarized spacer 137 and the second insulating layer pattern 155 may be substantially coplanar as the top surface of the first insulating layer pattern 120.

Referring to FIG. 12, a phase change material layer 160 is formed to be in contact with the top surfaces of the first insulating layer pattern 120, the planarized spacer 137, the first conductive pattern 145 and the second insulating layer pattern 155. A third insulating layer 170 is then formed on the phase change material layer 160 and the first insulating layer pattern 120. A second conductive pattern 180 is formed in the third insulating layer 170 to be electrically connected to the phase change material layer 160. The third insulating layer 170 may, for example, comprise silicon oxide, silicon nitride, or the like or combinations thereof. A second interconnection 190 may be formed on the third insulating layer 170 as shown in FIG. 1. The second interconnection 190 may be formed to cover the second conductive pattern 180.

The second conductive pattern 180 and the second interconnection 190 may, for example, comprise aluminum, tungsten silicide, copper, titanium tungsten, tantalum, molybdenum, tungsten, an alloy layer of aluminum and copper, an alloy layer of aluminum, copper and silicon, or the like or combinations thereof.

According to the embodiments described above, the second insulating layer pattern 155 may comprise a material having the same or substantially the same etch selectivity (i.e., the same or substantially the same etch rate) as the first insulating layer pattern 120 or may comprise a material from the same system as the first insulating layer pattern 120. For example, if the first insulating layer pattern 120 comprises silicon nitride, then the second insulating layer pattern 155 may comprise a material such as silicon oxynitride (a material having substantially the same etch selectivity as silicon nitride, for purposes of the present embodiment) or silicon nitride (the same material as the first insulating layer pattern 120, therefore a material having the same etch selectivity as the first insulating layer pattern 120). Thus, the second insulating layer pattern 155 can be prevented from being over-etched during the second planarization process. As a result, the top surfaces of the first insulating layer pattern 120, the second insulating layer pattern 155 and the first conductive pattern 145 may be substantially coplanar and the phase change material layer 160 may contact a ring-shaped top surface 145au of the first conductive pattern 145 but may not contact any sidewall of the first conductive pattern 145. Accordingly, a contact area between the phase change material layer 160 and the first conductive pattern 145 may be minimized.

In other embodiments, the second planarization process described with respect to FIG. 11 may be omitted. Accordingly, the phase change material layer 160 may be formed after removal of the sacrificial layer 130 without use of the second planarization process.

In yet other embodiments, the sacrificial layer 130 may not be removed and the second planarization process may not be performed. Accordingly, the phase change material layer 160 may be formed on the sacrificial layer 130, the insulating spacer 135, the preliminary first conductive pattern 143 and the preliminary second insulating layer pattern 153 after the first planarization process described with respect to FIG. 9.

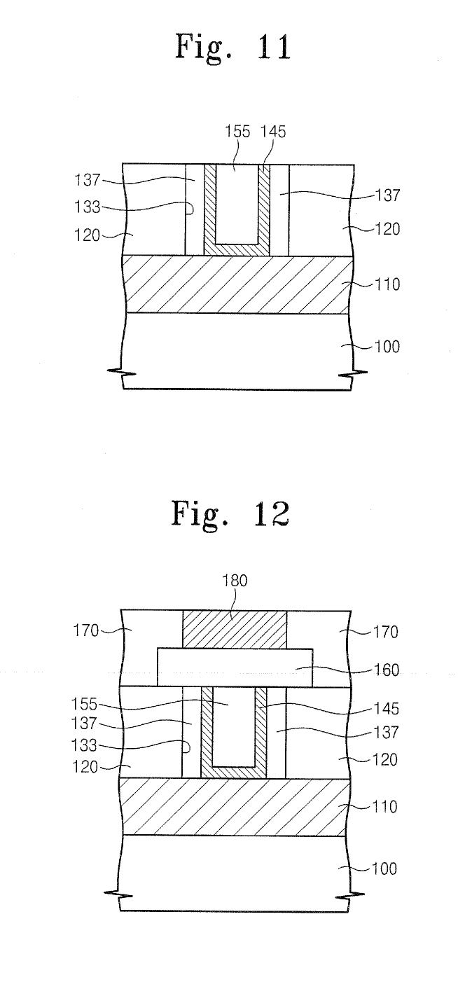

In still other embodiments, the sacrificial layer 130 may not be formed. In this case, the process for removing the sacrificial layer and the second planarization process may not be carried out. Accordingly, the method of fabricating the phase change memory cell may be exemplarily characterized as forming a first insulating layer pattern having an opening on a substrate and a first interconnection, forming an insulating spacer on a sidewall of the opening, forming a first conductive layer on the substrate having the spacer, forming a second insulating layer on the first conductive layer, planarizing the second insulating layer to form a second insulating layer pattern in the opening, removing the first conductive layer outside the opening using a first planarization process to form a first conductive pattern in the opening, forming a phase change material layer, and forming a second conductive layer. In such an embodiment, the first insulating layer and/or the second insulating layer pattern may be over-etched during the first planarization process for removing portions of the first conductive layer outside the opening. Hence, the top surfaces of the first insulating layer and/or the second insulating layer pattern may be lower than the top surface of the first conductive pattern, thereby exposing upper sidewalls of the first conductive pattern. Thus, protection spacers may be formed on the upper sidewalls of the first conductive pattern to prevent the phase change material layer from contacting upper sidewalls of the first conductive pattern. These embodiments will now be described with reference to FIGS. 13 to 15 in more detail.

Referring to FIG. 13, a second insulating layer pattern 255 may be formed in the opening 133 to be surrounded by the first conductive pattern 145, and the top surface of the second insulating layer pattern 255 may be lower than the top surface of the first conductive pattern 145. Thus, upper portions of inner sidewalls of the first conductive pattern 145 may be exposed. A protection spacer 238 is formed to cover the exposed inner sidewalls of the first conductive pattern 145. A phase change material layer 260 is then formed on the substrate having the protection spacer 238 to thereby contact the top surface of the first conductive pattern 145. As a result, the phase change material layer 260 may not directly contact the inner sidewalls of the first conductive pattern 145 because of the presence of the protection spacers 238.

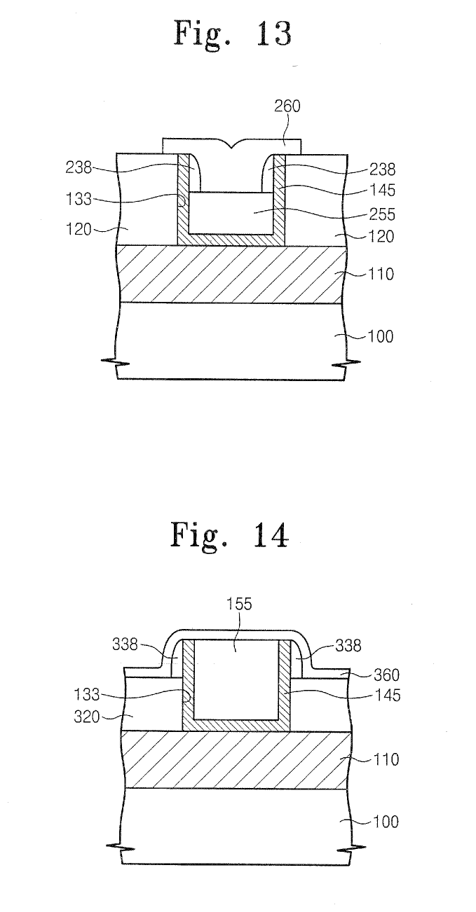

Referring to FIG. 14, a first insulating layer 220 may be formed to be lower than the first conductive pattern 145. That is, the top surface of the first insulating layer 220 may be lower than the top surface of the second insulating 155 and the first conductive pattern 145. Thus, upper portions of outer sidewalls of the first conductive pattern 145 may be exposed. A protection spacer 338 is formed to cover the exposed outer sidewalls of the first conductive pattern 145. A phase change material layer 360 is then formed on the substrate having the protection spacer 338 to thereby contact the top surface of the first conductive pattern 145. As a result, the phase change material layer 360 may not directly contact the outer sidewalls of the first conductive pattern 145 because of the presence of the protection spacers 338.

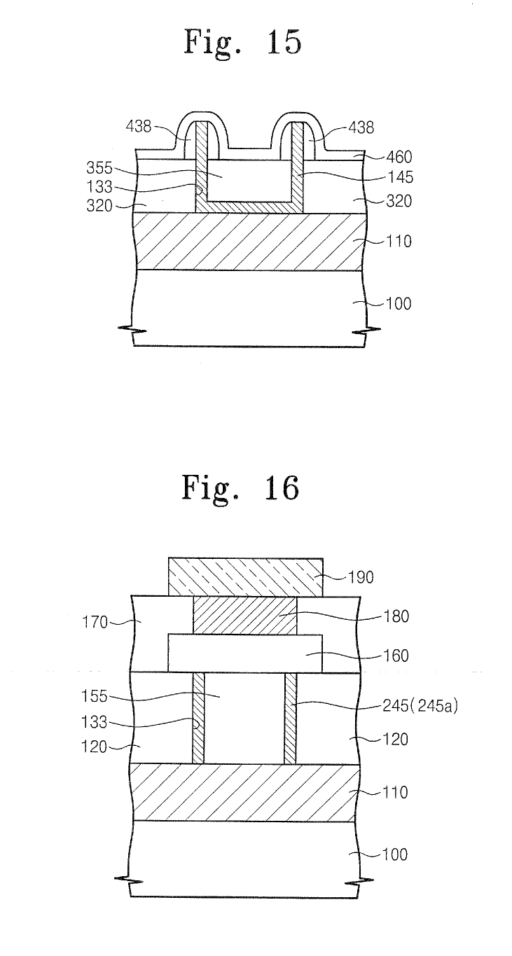

Referring to FIG. 15, a first insulating layer 320 and a second insulating layer pattern 355 may be formed to be lower than the first conductive pattern 145. That is, the top surfaces of the first insulating layer 320 and the second insulating layer pattern 355 may be lower than the top surface of the first conductive pattern 145. Thus, upper portions of outer and inner sidewalls of the first conductive pattern 145 may be exposed. Protection spacers 438 are formed to cover the exposed inner and outer sidewalls of the first conductive pattern 145. A phase change material layer 460 is then formed on the substrate having the protection spacers 438 to thereby contact the top surface of the first conductive pattern 145. As a result, the phase change material layer 460 may not directly contact the inner and outer sidewalls of the first conductive pattern 145 because of the presence of the protection spacers 438.

In the embodiments exemplarily described with reference to FIGS. 13 to 15, the first insulating layer and the second insulating layer patterns may comprise silicon oxide (e.g., a layer of silicon oxide). Alternatively, the first insulating layers and the second insulating layer patterns may comprise silicon oxide, silicon nitride, silicon oxynitride or the like or combinations thereof. Further, the spacer 137 and/or the third conductor 139, described with reference to FIGS. 3 and 4, may be incorporated within the structures exemplarily described with respect to FIGS. 13 to 15.

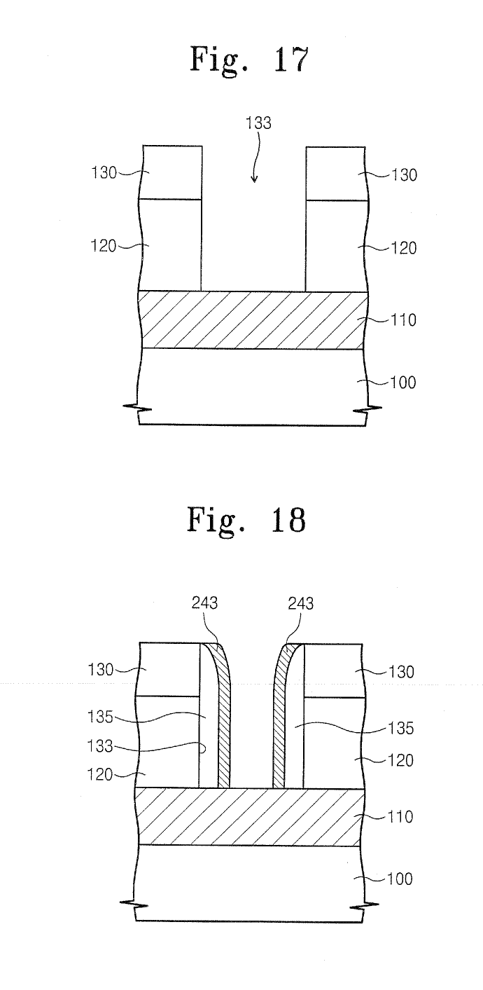

FIG. 16 is a cross sectional view illustrating a phase change memory cell according to yet another embodiment.

Referring to FIG. 16, a first conductive pattern 245 may be disposed only on the sidewall of the opening 133 which penetrates the first insulating layer pattern 120. That is, the first conductive pattern 245 may include a vertical portion 245a and the second insulating layer pattern 155 may directly contact the first conductor 110. A top surface of the first conductive pattern 245 may have a ring-shaped configuration when viewed from a top plan view, and the top surface of the first conductive pattern 245 may contact the phase change material layer 160.

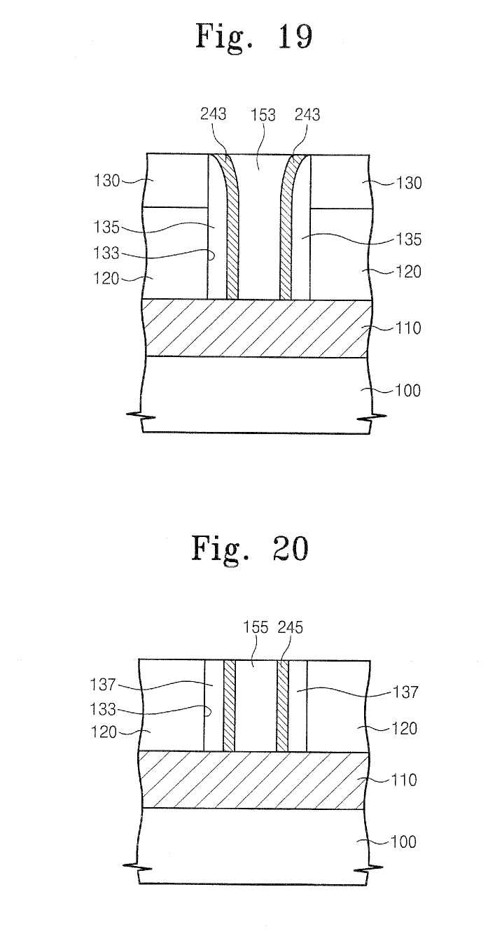

FIGS. 17 to 20 are cross sectional views illustrating methods of fabricating the phase change memory cell exemplarily shown in FIG. 16.

Referring to FIGS. 17 and 18, the first interconnection 110, the first insulating layer pattern 120 the sacrificial layer 130 having the opening 133, and the spacer 135 may be formed using, for example, the same methods as described with reference to FIG. 5. A conductive layer may be formed on the substrate having the spacer 135, and the conductive layer may then be anisotropically etched to form a preliminary first conductive pattern 243 on the inner sidewall of the spacer 135.

Referring to FIGS. 19 and 20, a preliminary second insulating layer pattern 153 is formed to substantially fill the opening 133 and is laterally surrounded by the preliminary first conductive pattern 243. The preliminary second insulating layer pattern 153 may be formed by depositing a second insulating material on the substrate having the preliminary first conductive pattern 243 and selectively removing portions of the second insulating material outside the opening 133 using a first planarization process such as the first planaraization process described above. The sacrificial layer 130 is then removed. As a result, upper portions of the spacer 135, the preliminary first conductive pattern 243 and the preliminary second insulating pattern 153 may protrude above the top surface of the first insulating layer pattern 120. The protruding portions of the spacer 135, the preliminary first conductive pattern 243 and the preliminary second insulating pattern 153 may be removed using a second planarization process such as the first planaraization process described above, thereby forming a planarized spacer 137, a first conductive pattern 245 and a second insulating layer pattern 155.

Although not shown in the figures, a phase change material layer, a third insulating layer, a second conductive pattern and a second interconnection may be formed after the second planarization process using the same methods as described with reference to FIG. 12.

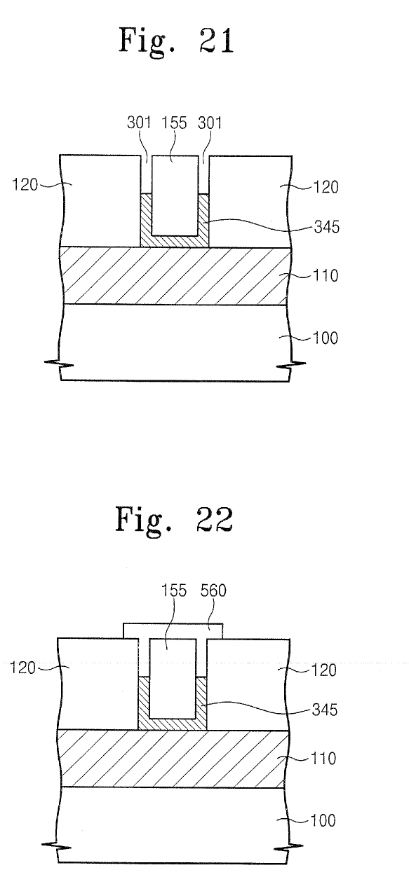

In some embodiments, the first conductive pattern 145 or 245 may be recessed prior to formation of the phase change material layer 160. Accordingly, a top surface of the recessed first conductive pattern may be lower than the top surfaces of the first insulating layer pattern 120 and the second insulating layer pattern 155. The method of fabricating a phase change memory cell having the recessed conductive pattern will be described with reference to FIGS. 21 and 22.

Referring to FIGS. 21 and 22, after the second planarization process, the first conductive pattern 145 or 245 may be partially etched to form a recessed conductive pattern 345. As a result, a top surface the recessed conductive pattern 345 may be lower than the top surface of the first insulating layer and a ring-shaped opening 301 may be defined over the recessed conductive pattern 345. A phase change material layer 560 is then formed to fill the ring-shaped opening 301 on the first insulating layer pattern 120 and the second insulating layer pattern 155.

According to the above embodiment, the phase change material layer 560 may contact the recessed conductive pattern 345 inside the ring-shaped opening 301 and phase changes may occur within the ring-shaped opening 301.

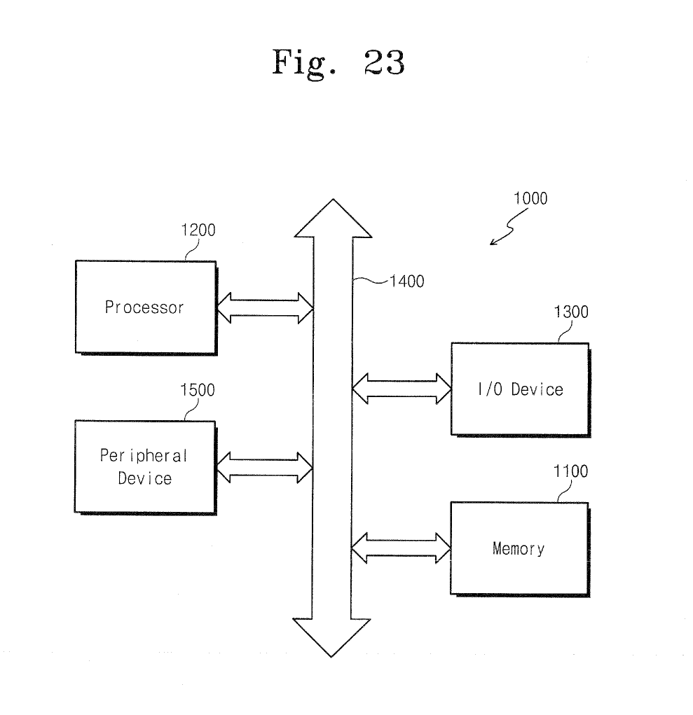

FIG. 23 is an exemplary data processing system 1000 that employs a phase change memory device including a plurality of phase change memory cells according to the embodiments described above as a memory device 1100. The data processing system 1000 may, for example, include a processor 1200 (e.g., a micro processor, a digital signal processor or a programmable logic device), and the processor 1200 may communicate with an input/output (I/O) unit 1300 through a bus 1400. The memory device 1100 may communicate with the I/O unit 1300 and/or the processor 1200 through a memory controller on the bus 1400. The data processing system 1000 may further include a peripheral unit 1500 having at least one of a hard disk driver, a floppy disk driver and a compact disk read only memory (CD ROM) driver, and the peripheral unit 1500 may communicate with the processor 1200 on the bus 1400. The memory device 1100 may include one or more phase change memory devices. The memory device 1100 and the processor 1200 may be formed in a single integrated circuit chip.

Further, the data processing system 1000 is applicable to a personal data assistant (PDA), a portable computer, a cellular phone, a digital music player, a digital camera or another wireless system.

According to the embodiments exemplarily described above, a contact area between a phase change material layer and a bottom electrode may be minimized.

While embodiments of the present invention have been particularly shown and described with reference to the drawings included herein, it will be understood by those of ordinary skill in the art that various changes in form and details may be made therein without departing from the spirit and scope of the present invention as defined by the following claims.

What is claimed is:

1. A method of forming a semiconductor memory device, comprising:
forming a first insulating layer pattern and a sacrificial layer on a substrate, the sacrificial layer having an etch selectivity with respect to the first insulating layer pattern and the first insulating layer pattern and the sacrificial layer having an opening defined therein;
forming a preliminary first conductive pattern on a sidewall of the opening;
forming a preliminary second insulating layer pattern within the opening, wherein at least a portion of at least one of the preliminary first conductive pattern and the preliminary second insulating layer pattern is over the first insulating layer pattern;
removing the sacrificial layer and portions of the preliminary first conductive pattern and the preliminary second insulating layer pattern over the first insulating layer pattern, thereby forming a first conductor and a second insulating layer pattern;
forming a phase change material layer on the first conductor, the first insulating layer and the second insulating layer pattern; and
forming a second conductor on the phase change material layer.

2. The method of claim 1, wherein removing the sacrificial layer and the portions of the preliminary first conductive pattern and the preliminary second insulating layer pattern over the first insulating layer comprises:
removing the sacrificial layer; and
planarizing the preliminary first conductive pattern and the preliminary second insulating layer pattern such that top surfaces of the first conductor and the second insulating layer pattern are substantially coplanar with a top surface of the first insulating layer pattern.

3. The method of claim 2, wherein removing the sacrificial layer comprises selectively removing the sacrificial layer with respect to the preliminary first conductive pattern and the preliminary second insulating layer pattern.

4. The method of claim 1, wherein the first insulating layer pattern and the second insulating layer pattern comprise silicon nitride, silicon oxynitride or combinations thereof and wherein the sacrificial layer comprises silicon oxide, silicon, aluminum oxide, titanium oxide or a combination thereof.

5. The method of claim 1, wherein the first conductor comprises titanium nitride layer, tantalum nitride, titanium aluminum nitride, titanium silicon nitride, tantalum silicon nitride, tantalum aluminum nitride, tungsten silicide, titanium tungsten or a combination thereof.

6. The method of claim 1, further comprising forming an insulating spacer on a sidewall of the opening before forming the preliminary first conductive pattern.

7. The method of claim 6, wherein the insulating spacer comprises a material having an etch selectivity with respect to the sacrificial layer.

8. The method of claim 1, wherein forming the preliminary first conductive pattern comprises:
forming a first conductive layer on the sidewall of the opening and on a top surface of the sacrificial layer; and
removing portions of the first conductive layer on the top surface of the sacrificial layer.

9. The method of claim 8, wherein forming the preliminary second insulating layer pattern comprises forming an insulating material on the first conductive layer.

10. The method of claim 9, wherein forming the preliminary second insulating layer pattern further comprises removing a portion of the insulating material such that a top surface of the remaining insulating material is substantially coplanar with a top surface of the first insulating layer pattern or above the top surface of the first insulating layer pattern.

11. A method of forming a semiconductor memory device, comprising:
forming a first insulating layer pattern and a sacrificial layer on a substrate, the sacrificial layer having an etch selectivity with respect to the first insulating layer pattern and the first insulating layer pattern and the sacrificial layer having an opening defined therein;
forming a preliminary first conductive pattern on a bottom surface of the opening and on a sidewall of the opening;
forming a preliminary second insulating layer pattern on the preliminary first conductive pattern, the preliminary second insulating layer pattern substantially filling the opening, wherein at least a portion of at least one of the preliminary first conductive pattern and the preliminary second insulating layer pattern is over the first insulating layer pattern;
removing the sacrificial layer and portions of the preliminary first conductive pattern and the preliminary second insulating layer pattern over the first insulating layer pattern, thereby forming a first conductor and a second insulating layer pattern;
forming a phase change material layer on the first conductor, the first insulating layer and the second insulating layer pattern; and
forming a second conductor on the phase change material layer.

12. The method of claim 11, wherein removing the sacrificial layer and portions of the preliminary first conductive pattern and the preliminary second insulating layer pattern over the first insulating layer comprises:
selectively removing the sacrificial layer with respect to the preliminary first conductive pattern and the preliminary second insulating layer pattern such that portion of the first insulating layer pattern outside the opening is exposed; and
planarizing the preliminary first conductive pattern and the preliminary second insulating layer pattern such that top surfaces of the first conductor and the second insulating layer are substantially coplanar with a top surface of the first insulating layer pattern.

13. The method of claim 11, wherein the first insulating layer pattern and the second insulating layer pattern comprise silicon nitride, silicon oxynitride or a combination thereof and wherein the sacrificial layer comprises silicon oxide, silicon, aluminum oxide, titanium oxide or a combination thereof.

14. The method of claim 11, wherein the first conductor comprises titanium nitride, tantalum nitride, titanium aluminum nitride, titanium silicon nitride, tantalum silicon nitride, tantalum aluminum nitride, tungsten silicide, titanium tungsten or a combination thereof.

15. The method of claim 11, further comprising forming an insulating spacer on a sidewall of the opening before forming the preliminary first conductive pattern.

16. The method of claim 15, wherein the insulating spacer comprises a material having an etch selectivity with respect to the sacrificial layer.

17. The method of claim 11, wherein forming the preliminary first conductive pattern comprises forming a first conductive layer on the bottom surface of the opening and outside the opening.

18. The method of claim 17, wherein forming the preliminary second insulating layer pattern comprises forming an insulating material on the first conductive layer and selectively removing a portion of the insulating material such that a top surface of the remaining insulating material is substantially coplanar with a top surface of the first insulating layer pattern or above the top surface of the first insulating layer pattern.

19. The method of claim 18, wherein forming the preliminary first conductive pattern further comprises planarizing the first conductive layer using the sacrificial layer and the remaining insulating material as a planarizing stopper.

20. A semiconductor memory device, comprising:
a first insulating layer pattern on a substrate, the first insulating layer pattern having an opening defined therein;
a first conductor covering at least a sidewall of the opening;
a second insulating layer pattern within the opening;
a phase change material layer on the first conductor, on the first insulating layer and on the second insulating layer pattern; and
a second conductor on the phase change material layer,
wherein the first insulating layer pattern and the second insulating layer pattern comprise silicon nitride, silicon oxynitride or a combination thereof.

21. The semiconductor memory device of claim 20, wherein the second insulating layer pattern substantially fills the opening.

22. The semiconductor memory device of claim 20, wherein a top surface of the first conductor has a closed configuration.

23. The semiconductor memory device of claim 22, wherein the closed configuration comprises a circular ring, an oval-shaped ring or a polygonal shape.

24. The semiconductor memory device of claim 20, wherein a top surface of the first conductor is substantially coplanar with top surfaces of the first insulating layer pattern and the second insulating layer pattern.

25. The semiconductor memory device of claim 20, wherein the first conductor protrudes above a top surface of at least one of the first insulating layer pattern and the second insulating layer pattern, the semiconductor memory device further comprising:
a protection spacer covering at least one of an inner sidewall and an outer sidewall of the first conductor.

26. The semiconductor memory device of claim 25, wherein the protection spacer comprises a material having an etch selectivity with respect to the first insulating layer pattern and the second insulating layer pattern.

27. The semiconductor memory device of claim 25, wherein the phase change material layer contacts a top surface of the first conductor.

28. The semiconductor memory device of claim 20, wherein a top surface of the first conductor is lower than top surfaces of the first insulating layer pattern and the second insulating layer pattern.

29. A semiconductor memory device, comprising:
a first insulating layer pattern on a substrate, the first insulating layer pattern having an opening defined therein;
a second insulating layer pattern within the opening;
a first conductor between at least a portion of a sidewall of the opening and the second insulating layer pattern, wherein a top surface of the first conductor is above a top surface of at least one of the first insulating layer pattern and the second insulating layer pattern;
a protection spacer on at least one sidewall of the first conductor adjoining the top surface of the first conductor;
a phase change material layer on the first conductor, the protection spacer and at least one of the first insulating layer pattern and the second insulating layer pattern; and
a second conductor on the phase change material layer.

30. A data processing system, comprising:
a processor; and
a memory device in communication with the processor and including at least one phase change memory device having a plurality of semiconductor memory cells, each of the semiconductor memory cells comprising:
a first insulating layer pattern on a substrate, the first insulating layer pattern having an opening defined therein;
a first conductor covering at least a sidewall of the opening;
a second insulating layer pattern within the opening;
a phase change material layer on the first conductor, on the first insulating layer and on the second insulating layer pattern; and
a second conductor on the phase change material layer,
wherein the first insulating layer pattern and the second insulating layer pattern comprise silicon nitride, silicon oxynitride or a combination thereof.
